(19) United States
(12) Patent Application Publication
(10) Pub. No.: US 2022/0299862 A1
(43) Pub. Date: Sep. 22, 2022

(54) REFLECTIVE MASK BLANK FOR EUV LITHOGRAPHY, REFLECTIVE MASK FOR EUV LITHOGRAPHY, AND METHOD FOR MANUFACTURING MASK BLANK AND MASK

(71) Applicant: AGC Inc., Tokyo (JP)

(72) Inventors: Daijiro AKAGI, Tokyo (JP); Hirotomo KAWAHARA, Tokyo (JP); Hiroyoshi TANABE, Tokyo (JP); Toshiyuki UNO, Tokyo (JP)

(73) Assignee: AGC Inc., Tokyo (JP)

(21) Appl. No.: 17/835,742

(22) Filed: Jun. 8, 2022

Related U.S. Application Data
(63) Continuation of application No. PCT/JP2020/047574, filed on Dec. 18, 2020.

(30) Foreign Application Priority Data
Dec. 27, 2019 (JP) 2019-238187

(51) Int. Cl. G03F 1/24; G03F 1/26; G03F 1/52; G03F 1/80

(52) U.S. Cl. CPC G03F 1/24; G03F 1/26; G03F 1/52; G03F 1/80

(57) ABSTRACT

A reflective mask blank for EUV lithography includes, in the following order, a substrate, a multilayer reflective film for reflecting EUV light, a phase shift film for shifting a phase of EUV light, and an etching mask film. The phase shift film is constituted of a ruthenium-based material containing ruthenium as a main component. The phase shift film has a film thickness of 20 nm or larger. The etching mask film is removable with a cleaning liquid comprising an acid or a base.

### CROSS-REFERENCE TO RELATED APPLICATIONS

This is a bypass continuation of International Patent Application No. PCT/JP2020/047574, filed on Dec. 18, 2020, which claims priority to Japanese Patent Application No. 2019-238187, filed on Dec. 27, 2019. The contents of these applications are hereby incorporated by reference in their entireties.

### TECHNICAL FIELD

The present invention relates to a reflective mask blank for EUV (Extreme Ultra Violet) lithography (in the present description, hereinafter referred to as “EUV mask blank”) for use in semiconductor production, etc., and to a reflective mask for EUV lithography and methods for producing these.

### BACKGROUND ART

Conventionally, in the semiconductor industry, a photolithography method using visible light or ultraviolet light has been employed as a fine-pattern transfer technique necessary for forming an integrated circuit configured of fine patterns on a Si substrate, etc. However, miniaturization of a semiconductor device has been accelerated, and on the other hand, the conventional photolithography method is approaching its limit. In the case of the photolithography method, the resolution limit of a pattern is about ½ of the exposure wavelength. Even if an immersion method is used, the resolution limit is said to be about ¼ of the exposure wavelength, and even if an immersion method with an ArF laser (193 nm) is used, the resolution limit is estimated to be approximately from 20 nm to 30 nm. From this point of view, EUV lithography, which is an exposure technique using EUV light having a wavelength shorter than that of ArF lasers, is expected to be promising as an exposure technique next to the 20-30 nm generation. In this description, the term “EUV light” means a ray having a wavelength in a soft X-ray range or a vacuum ultraviolet range, specifically, a ray having a wavelength of approximately from 10 nm to 20 nm, particularly about 13.5±0.3 nm.

EUV light is readily absorbed by various substances, and the refractive index of the substance at such a wavelength is close to 1. Therefore, a refractive optical system such as conventional photolithography using visible light or ultraviolet light cannot be employed. For this reason, in the EUV lithography, a catoptric system, i.e., a system using a reflective mask and a mirror, is employed.

Meanwhile, apart from the use of shorter-wavelength light, a resolution-improving technique utilizing a phase shift mask has been proposed. A phase shift mask is a mask having a mask pattern in which a transmitting portion differs in constituent substance or shape from an adjoining transmitting portion so that a phase difference of 180° is given to the light which has passed through these transmitting portions. Consequently, in the region lying between the two transmitting portions, the transmitted/diffracted light rays differing in phase by 180° diminish each other to considerably reduce the light intensity. This improves the mask contrast, resulting in an increased focal depth during transfer and in an improvement in transfer accuracy. Although the phase difference is most preferably 180° in theory, the resolution-improving effect is sufficiently obtained when the actual phase difference is about from 175° to 185°.

A half-tone mask is a kind of phase shift mask, in which, as a mask-pattern-constituting material, a thin film semi-transparent to exposure light is used as a half-tone film to reduce the transmittance to about several percents (usually about 2% or more and 15% or less of that for the light passed through the substrate) and to give a phase difference of about from 175° to 185° with respect to the light which has passed through ordinary substrates, thereby improving the resolution of pattern-edge portions to improve the transfer accuracy.

A proper range of transmittance in half-tone masks is explained here. Half-tone masks for conventional excimer lasers desirably satisfy an optical requirement that the half-tone film has a transmittance for ultraviolet light, as exposure wavelength, of generally from 2% to 15%. The reasons for this are as follows. First, in case where the transmittance of the half-tone film has a transmittance at the exposure wavelength of less than 2%, diffracted light rays of the light which has passed through adjoining transmitting pattern portions show a reduced mutually diminishing effect when superimposed on each other. Conversely, in case where the transmittance thereof exceeds 15%, the resultant resolution exceeds the resolution limit of the resist under some exposure conditions and an unnecessary pattern is undesirably formed in the regions of the half-tone film through which the light has passed.

EUV exposure employs a catoptric system in which the NA (numerical aperture) is small and the wavelength is short, and hence has a peculiar problem in that pattern transfer is prone to be affected by surface irregularities of the mirror and mask and it is not easy to accurately resolve desired fine line widths. In view of this, half-tone EUV masks have been proposed in which the principle of a half-tone mask used in conventional excimer laser exposure, etc. is made applicable to EUV exposure employing a catoptric system (see, for example, Patent Literatures 1 and 2).

Also in reflective masks such as EUV masks, the improvement in resolution by the phase shift effect is attained on the same principle. Hence, the “transmittance” is replaced by “reflectance”. Proper values of the EUV light reflectance of the phase shift film are thought to be from 2% to 20%.

With respect to phase differences, it is thought that in the case where the phase difference with respect to light reflected from a reflective layer that reflects EUV light is about from 150° to 250°, the pattern-edger portions have improved resolution to improve the transfer accuracy (see, for example, Non-Patent Literature 1).

The use of a half-tone EUV mask is in theory an effective means for improving resolution in EUV lithography. However, in half-tone EUV masks also, optimal reflectances depend on exposure conditions and the pattern to be transferred and it is difficult to unconditionally set a reflectance.

Furthermore, since EUV exposure is reflective exposure, incident light enters the EUV mask not vertically but from a slightly oblique (usually about 6°) direction and is converted to reflected light by the EUV mask. In the EUV mask, the layer which has been processed so as to have a pattern is a phase shift film. However, since EUV light enters from an oblique direction, a shadow of the pattern is cast. Because of this, a transferred resist pattern formed on the wafer by the reflected light has shifted from the original pattern position, depending on incidence direction and pattern arrangement direction. This is called a shadowing effect and is a problem in EUV exposure. A method for lessening the shadowing effect is to reduce the length of the shadow, and this may be attained by minimizing the height of the pattern. For reducing the pattern height, it is necessary to reduce the thickness of the phase shift film as much as possible.

With the recent trend toward miniaturization and density increase in patterns, there is a desire for a pattern having higher resolution. For obtaining a pattern having high resolution, it is necessary for the resist to have a reduced film thickness. However, use of a resist having a reduced film thickness results in a possibility that the pattern transferred to the phase shift film might have reduced accuracy due to resist-film consumption during the etching step.

In order to solve the problem, a reduction in resist film thickness can generally be attained by disposing a layer (etching mask film) of a material having resistance to etching conditions for the phase shift film, on the phase shift film. That is, a reduction in resist film thickness can be attained by forming such an etching mask film so that the etching mask film has a reduced relative etching rate (etching selectivity), with respect to the etching rate of the phase shift film under etching conditions therefor, which is taken as 1. The half-tone EUV masks described in Patent Literatures 1 and 2 employ etching mask films which are a layer containing both Si and N or a tantalum-based-material layer containing tantalum, thereby attaining a reduction in resist film thickness.

However, the half-tone EUV masks described in Patent Literatures 1 and 2 each employ a phase shift film configured of two layers, a Ta-based-material layer containing tantalum (Ta) and a Ru-based-material layer containing ruthenium (Ru), and hence necessitate different etching processes for the respective layers of the phase shift film in patterning the phase shift film. Because of this, the process of patterning the phase shift film is complicated.

Meanwhile, in Non-Patent Literature 1, it has been reported that by using a Ru-based material to form a phase shift layer in a given film thickness, an improvement in the resolution of pattern-edge portions is attained to improve the transfer accuracy, without forming two phase shift layers.

It is hence thought that with a phase shift layer including a Ru-based material, it is possible to attain the optical properties required of phase shift films, a reduction in the thickness of phase shift films, and simplification of processes for patterning phase shift films.

### CITATION LIST

### Patent Literature

Patent Literature 1: Japanese Patent No. 5,282,507
Patent Literature 2: Japanese Patent No. 6,381,921

### Non-Patent Literature

Non-Patent Literature 1: Alternative reticles for low-kl EUV imaging, M.-Claire van Lare, Frank J. Timmermans, Jo Finders, Proc. SPIE 11147, International Conference on Extreme Ultraviolet Lithography 2019, 111470D (26 Sep. 2019)

### SUMMARY OF INVENTION

### Technical Problems

The conventional etching mask films include ones constituted of a Cr-based material containing chromium (Cr) and ones constituted of a Ta-based material containing Ta. However, there are the following problems in the case where a conventional hard mask film is applied to the phase shift layer constituted of a Ru-based material.

In patterning the phase shift layer constituted of a Ru-based material, dry etching is conducted in which either oxygen gas or a mixed gas of oxygen gas and a halogen-based gas (chlorine-based gas or fluorine-based gas) is used as an etching gas. However, the etching mask film constituted of a Cr-based material is etched by dry etching with the mixed gas as an etching gas and is hence unable to function as an etching mask film.

The etching mask film constituted of a Ta-based material is not etched by dry etching with the mixed gas as an etching gas. However, after the phase shift film has been patterned, a process of dry etching with a specific etching gas is necessary for removing the etching mask film present on the phase shift film. Hence, the troublesomeness of patterning process remains unsolved.

An object of the present invention is to provide, in order to overcome the problems of the prior-art techniques, an EUV mask blank including a phase shift layer including a Ru-based material and an etching mask film which has etching resistance to dry etching with either oxygen gas or a mixed gas of oxygen gas and a halogen-based gas (chlorine-based gas or fluorine-based gas) as an etching gas and which can be removed without using a dry etching process.

### Solution to the Problems

In order to overcome the problems, the present inventors provide a reflective mask blank for EUV lithography which includes a substrate and, formed on or above the substrate in the following order, a multilayer reflective film for reflecting EUV light, a phase shift film for shifting a phase of EUV light, and an etching mask film, wherein the phase shift film is constituted of a ruthenium-based material including ruthenium as a main component, the phase shift film having a film thickness of 20 nm or larger, and the etching mask film is removable with a cleaning liquid including an acid or a base.

### Advantageous Effects of Invention

The etching mask film in the EUV mask blank of the present invention has etching resistance to dry etching with either oxygen gas or a mixed gas of oxygen gas and a halogen-based gas (chlorine-based gas or fluorine-based gas) as an etching gas and which can be removed without using a dry etching process.

### BRIEF DESCRIPTION OF DRAWINGS

FIG. 1 is a schematic cross-sectional diagram illustrating one embodiment of the EUV mask blank of the present invention.

FIG. 2 is a diagram for showing a procedure for forming a pattern in the EUV mask blank 1 shown in FIG. 1, in which a resist film 20 has been formed on the etching mask film 15 of the EUV mask blank 1.

FIG. 3 is a diagram showing a step succeeding FIG. 2; a resist pattern 200 has been formed in the resist film 20.

FIG. 4 is a diagram showing a step succeeding FIG. 3; an etching mask film pattern 150 has been formed in the etching mask film 15.

FIG. 5 is a diagram showing a step succeeding FIG. 4; a phase shift film pattern 140 has been formed in the phase shift film 14.

FIG. 6 is a diagram showing a step succeeding FIG. 5; the resist film 20 and the etching mask film 15 have been removed and the phase shift film pattern 140 is exposed.

FIG. 7 is a diagram in which etching rates in dry etching with a mixed gas of oxygen gas and chlorine gas are compared.

FIG. 8 is a diagram in which etching selectivities with respect to Ru are compared.

FIG. 9 is a diagram in which film thickness losses through SPM cleaning are compared.

FIG. 10 is a diagram showing a relationship between the film thickness of an RuON film and the reflectance of the RuON film and a relationship between the film thickness of the RuON film and phase differences between light reflected from the RuON film and light reflected from a multilayer reflective film.

### DESCRIPTION OF EMBODIMENTS

The EUV mask blank of the present invention is described below by referring to the drawings.

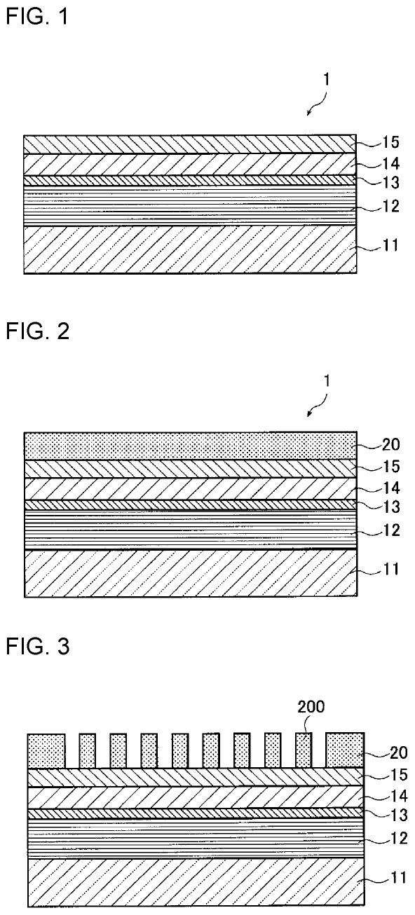

FIG. 1 is a schematic cross-sectional diagram illustrating one embodiment of the EUV mask blank of the present invention. In the EUV mask blank 1 illustrated in FIG. 1, a multilayer reflective film 12 for reflecting EUV light, a protective film 13 for the multilayer reflective film 12, a phase shift film 14 for shifting the phase of EUV light, and an etching mask film 15 have been formed in this order on or above a substrate 11. In the configuration illustrated in FIG. 1 of the EUV mask blank of the present invention, only the substrate 11, multilayer reflective film 12, phase shift film 14, and etching mask film 15 are essential, and the protective film 13 is an optional constituent element.

The protective film 13 for the multilayer reflective film 12 is provided for the purpose of protecting the multilayer reflective film 12 in patterning the phase shift film 14.

The constituent elements of the EUV mask blank 1 are described below.

The substrate 11 satisfies properties required of substrates for EUV mask blanks. The substrate 11 hence has a low coefficient of thermal expansion (specifically, the coefficient of thermal expansion at 20° C. is preferably 0±0.05×10⁻⁷/° C., more preferably 0±0.03×10⁻⁷/° C.) and is excellent in terms of smoothness, flatness, and resistance to cleaning liquids including an acid or a base. As the substrate 11, specifically, a glass having a low coefficient of thermal expansion, for example, a SiO₂—TiO₂ glass, is used. However, the substrate 11 is not limited thereto, and use can be made of substrates such as a crystallized glass in which β-quartz solid solution has been precipitated, a silica glass, silicon, and a metal.

The substrate 11 preferably has a smooth surface with a surface roughness (rms) of 0.15 nm or less and has a flatness of 100 nm or less, because high reflectance and transfer accuracy are obtained in a reflective mask after pattern formation. The surface roughness (rms) and the flatness can be determined with a scanning probe microscope (S-image, manufactured by SII NanoTechnology Inc.).

The size, thickness, etc. of the substrate 11 are appropriately determined in accordance with designed values, etc. of the mask. In the Example which is given later, a SiO₂—TiO₂ glass having an outer shape of 6-inch (152-mm) square and a thickness of 0.25 inch (6.3 mm) was used.

It is preferred that there are no defects in the surface of the substrate 11 on which the multilayer reflective film 12 is formed. However, the surface may have defects unless a phase defect is caused by a concave defect and/or a convex defect. Specifically, it is preferred that the depth of a concave defect and the height of a convex defect are 2 nm or less and the half widths of these concave and convex defects are 60 nm or less.

The multilayer reflective film 12 has been formed by alternately stacking a high-refractive-index layer and a low-refractive-index layer a plurality of times, thereby attaining a high EUV light reflectance. In the multilayer reflective film 12, Mo is widely used as the high-refractive-index layers and Si is widely used as the low-refractive-index layers. That is, a Mo/Si multilayer reflective film is most common. However, the multilayer reflective film is not limited thereto, and use can be made of a Ru/Si multilayer reflective film, a Mo/Be multilayer reflective film, a Mo compound/Si compound multilayer reflective film, a Si/Mo/Ru multilayer reflective film, a Si/Mo/Ru/Mo multilayer reflective film, and a Si/Ru/Mo/Ru multilayer reflective film.

The multilayer reflective film 12 is not particularly limited as long as it has properties required of the multilayer reflective films of reflective mask blanks. A property particularly required of the multilayer reflective film 12 is a high EUV light ray reflectance. Specifically, when the surface of the multilayer reflective film 12 is irradiated, at an incident angle of 6°, with light rays having wavelengths within a wavelength range of EUV light, then the maximum value of the reflectance for light having a wavelength of around 13.5 nm is preferably 60% or more, more preferably 65% or more. Also, even in the case of providing a protective film 13 on the multilayer reflective film 12, the maximum value of the reflectance for light having a wavelength of around 13.5 nm is preferably 60% or more, more preferably 65% or more.

The film thickness of each of the layers constituting the multilayer reflective film 12 and the number of repeating layer units can be appropriately selected in accordance with film materials used and the EUV light ray reflectance required of the multilayer reflective film. Taking a Mo/Si multilayer reflective film as an example, a multilayer reflective film 12 having a maximum value of EUV light ray reflectance of 60% or more may be obtained by forming the multilayer reflective film by stacking a Mo layer with a film thickness of 2.3±0.1 nm and a Si layer with a film thickness of 4.5±0.1 nm so that the number of repeating units is from 30 to 60 (preferably from 40 to 50).

Each of the layers constituting the multilayer reflective film 12 may be deposited in a desired thickness using a known deposition method such as magnetron sputtering method or ion beam sputtering method. For example, in the case of forming a Si/Mo multilayer reflective film using an ion beam sputtering method, it is preferred that a Si target is first used as a target and Ar gas (gas pressure, from 1.3×10⁻² Pa to 2.7×10⁻² Pa) is used as a sputtering gas under the conditions of an ion accelerating voltage of from 300 V to 1,500 V and a deposition rate of from 0.030 nm/sec to 0.300 nm/sec to deposit a Si layer in a thickness of 4.5 nm and subsequently a Mo target is used as a target and Ar gas (gas pressure, from 1.3×10⁻² Pa to 2.7×10⁻² Pa) is used as a sputtering gas under the conditions of an ion accelerating voltage of from 300 V to 1,500 V and a deposition rate of from 0.030 nm/sec to 0.300 nm/sec to deposit a Mo layer in a thickness of 2.3 nm. Taking these deposition steps as one cycle, the Si layer and the Mo layer are stacked, for example, in 30 to 60 cycles, preferably 40 to 50 cycles. Thus, a Si/Mo multilayer reflective film is deposited.

From the standpoint of preventing the surface of the multilayer reflective film 12 from oxidizing, the uppermost layer of the multilayer reflective film 12 is preferably a layer of a material unsusceptible to oxidation. The layer of a material unsusceptible to oxidation functions as a cap layer for the multilayer reflective film 12. Specific examples of the layer of a material unsusceptible to oxidation, which functions as a cap layer, include a Si layer. In the case where the multilayer reflective film 12 is Si/Mo films, the uppermost layer functions as a cap layer when it is a Si layer. In this case, the film thickness of the cap layer is preferably 11±2 nm.

The protective film 13 is provided for the purpose of protecting the multilayer reflective film 12 so that the multilayer reflective film 12 is not damaged by an etching process in patterning the phase shift film 14 by dry etching in which either oxygen gas or a mixed gas of oxygen gas and a halogen-based gas (chlorine-based gas or fluorine-based gas) is used as an etching gas. Consequently, selected as the material of the protective film 13 is a substance which is less affected by the process of etching the phase shift film 14, that is, a substance which has a lower etching rate than the phase shift film 14 under etching conditions for the phase shift film and which is less likely damaged by the etching process.

The protective film 13 preferably has an etching selectivity, with respect to the phase shift film 14 under etching conditions for the phase shift film 14, of ⅕ or less. The etching selectivity is determined using the following equation.

Etching selectivity=[etching rate of protective film 13]/[etching rate of phase shift film 14]

The protective film 13 preferably has resistance to cleaning liquids including an acid or a base which are used as resist-cleaning liquids in EUV lithography.

In order for the protective film 13 to satisfy those properties, the protective film 13 includes at least one element selected from the group consisting of Ru, platinum (Pt), palladium (Pd), iridium (Ir), rhodium (Rh), zirconium (Zr), niobium (Nb), Ta, titanium (Ti), and Si. However, since Ru is also a constituent material for the phase shift film 14, if Ru is to be used as a material for the protective film 13, an alloy thereof with other element(s) is used. Specific examples thereof include RuZr.

The protective film 13 may further contain at least one element selected from the group consisting of O, N, and B. That is, those elements may be in the form of oxides, nitrides, oxynitrides, or borides. Specific examples thereof include ZrO₂ and SiO₂.

The thickness of the protective film 13 is not particularly limited. In the case of a RuZr film, the thickness thereof is preferably from 2 nm to 3 nm.

The protective film 13 is deposited using a known deposition method such as magnetron sputtering method or ion beam sputtering method. For example, in the case of forming a RuZr film using a DC sputtering method, it is preferred that a RuZr target is used as a target and Ar gas (gas pressure, from 1.0×10⁻² Pa to 1.0×10° Pa) is used as a sputtering gas under the conditions of an input voltage of from 30 V to 1,500 V and a deposition rate of from 0.020 nm/sec to 1.000 nm/sec to deposit the film in a thickness of from 2 nm to 3 nm.

The phase shift film 14 is constituted of a Ru-based material including Ru as a main component. In this description, the expression “a Ru-based material including Ru as a main component” means a material including Ru in an amount of 30 at % or more.

The phase shift film 14 may be constituted of Ru only, but may contain elements other than Ru which contribute to the properties required of phase shift films. Specific examples of such elements include O and N. Specific examples of the phase shift film 14 containing one or more of these elements include a RuO₂ film and a RuON film.

The phase shift film 14 constituted of a Ru-based material, when having a film thickness of 20 nm or larger, can attain the optical properties which are desired to be possessed by the phase shift films of half-tone type EUV masks.

The phase shift film 14 has a reflectance for 13.53-nm wavelength of preferably from 3% to 30%, more preferably from 3% to 20%, still more preferably from 5% to 15%. The reflectance can be measured using an EUV reflectiometer (MBR, manufactured by AIXUV GmbH) for mask blanks.

The phase difference between the reflected light of EUV light from the phase shift film 14 and the reflected light of EUV light from the multilayer reflective film 12 is preferably from 150° to 250°, more preferably from 180° to 220°.

The phase shift film 14 constituted of a Ru-based material preferably has a film thickness of 45 nm or larger.

However, in the case where the film thickness of is too large, there is a possibility, for example, that the phase difference between the reflected light of EUV light from the phase shift film 14 and the reflected light of EUV light from the multilayer reflective film 12 might be too large to improve the transfer accuracy or that the patterning throughput might decrease. Because of this, the film thickness of the phase shift film 14 is preferably 60 nm or less, more preferably 55 nm or less.

The phase shift film 14 constituted of a Ru-based material is deposited using a known deposition method such as magnetron sputtering method or ion beam sputtering method. For example, in the case of forming a RuON film using a reactive sputtering method, it is preferred that a Ru target is used as a target and a mixed gas (gas pressure, from 1.0×10⁻² Pa to 1.0×10⁰ Pa) including Ar, O₂, and N₂ in a volume ratio of 5:1:1 is used as a sputtering gas under the conditions of an input voltage of from 30 V to 1,500 V and a deposition rate of from 0.020 nm/sec to 1.000 nm/sec to deposit the film in a thickness of from 45 nm to 55 nm.

The phase shift film 14 constituted of a Ru-based material can be etched by dry etching in which either oxygen gas or a mixed gas of oxygen gas and a halogen-based gas (chlorine-based gas or fluorine-based gas) is used as an etching gas. Specifically, the phase shift film 14 can be etched preferably at an etching rate of 10 nm/min or higher in dry etching in which either oxygen gas or a mixed gas of oxygen gas and a halogen-based gas (chlorine-based gas or fluorine-based gas) is used as an etching gas.

As the mixed gas of oxygen gas and a halogen-based gas, use is made of a mixed gas including oxygen gas in an amount of from 40 vol % to less than 100 vol %, preferably from 75 vol % to 90 vol %, and containing a chlorine-based gas or a fluorine-based gas in an amount of from more than 0 vol % to 60 vol %, preferably from 10 vol % to 25 vol %. Usable as the chlorine-based gas are chlorine-based gases such as Cl₂, SiCl₄, CHCl₃, CCl₄, and BCl₃ and mixtures of these gases. Usable as the fluorine-based gas are fluorine-based gases such as CF₄, CHF₃, SF₆, BF₃, and XeF₂ and mixtures of these gases.

The etching mask film 15 shows etching resistance to dry etching in which either oxygen gas or a mixed gas of oxygen gas and a halogen-based gas (chlorine-based gas or fluorine-based gas) is used as an etching gas.

In dry etching in which either oxygen gas or a mixed gas of oxygen gas and a halogen-based gas (chlorine-based gas or fluorine-based gas) is used as an etching gas, the etching mask film 15 preferably has an etching selectivity, with respect to the phase shift film 14, of 1/10 or less. The etching selectivity is determined using the following equation.

Etching selectivity=[etching rate of etching mask film 15]/[etching rate of phase shift film 14]

Meanwhile, the etching mask film 15 can be removed with cleaning liquids including an acid or a base which are used as resist-cleaning liquids in EUV lithography. The expression “an etching mask film can be removed with cleaning liquids including an acid or a base” means that the etching mask film, when immersed for 20 minutes in an acid or base having a given temperature, undergoes a loss in film thickness of 5 nm or more. The loss thereof is more preferably 10 nm or more. Specific examples of cleaning liquids to be used for that purpose include a sulfuric acid/hydrogen peroxide mixture (SPM), an ammonia/hydrogen peroxide mixture, and hydrofluoric acid. The SPM is a solution obtained by mixing sulfuric acid with hydrogen peroxide; sulfuric acid and hydrogen peroxide can be mixed together in a volume ratio of from 4:1 to 1:3, preferably 3:1. The temperature of the SPM at this time is preferably regulated to 100° C. or higher, from the standpoint of improving the etching rate. The ammonia/hydrogen peroxide mixture is a solution obtained by mixing ammonia with hydrogen peroxide; NH₄OH, hydrogen peroxide, and water can be mixed together in a volume ratio of from 1:1:5 to 3:1:5. The temperature of the ammonia/hydrogen peroxide mixture at this time is preferably regulated to 70 to 80° C.

The etching mask film 15 satisfying those properties preferably includes at least one element selected from the group consisting of Nb, Ti, Mo, and Si. The etching mask film 15 may further contain at least one element selected from the group consisting of O, N, and B. That is, those elements may be in the form of oxides, oxynitrides, nitrides, or borides. Specific examples of such constituent materials for the etching mask film 15 include Nb-based materials such as Nb, Nb₂O₅, and NbON. The etching mask film 15 constituted of any of these Nb-based materials can be etched by dry etching in which a chlorine-based gas is used as an etching gas. Specific examples of thereof further include Mo-based materials such as Mo, MoO₃, and MoON. The etching mask film 15 constituted of any of these Mo-based materials can be etched by dry etching in which a chlorine-based gas, for example, is used as an etching gas. Specific examples thereof furthermore include Si-based materials such as Si, SiO₂, and Si₃N₄. The etching mask film 15 constituted of any of these Si-based materials can be etched by dry etching in which a fluorine-based gas, for example, is used as an etching gas. In the case of using a Si-based material as the etching mask film 15, removal with hydrofluoric acid as a cleaning liquid is preferred.

The etching mask film 15 preferably has a film thickness of 20 nm or less, from the standpoint of removability with cleaning liquids. The film thickness of the etching mask film 15 constituted of a Nb-based material is preferably from 5 nm to 15 nm.

The etching mask film 15 can be formed by a known deposition method such as, for example, magnetron sputtering method or ion beam sputtering method.

In the case of forming a Nb₂O₅ film by a sputtering method, a reactive sputtering method using an Nb target may be conducted in a gaseous atmosphere obtained by mixing an inert gas including at least one selected from He, Ar, Ne, Kr, and Xe (hereinafter referred to simply as “inert gas”) with oxygen. In the case of using a magnetron sputtering method, the deposition may be conducted, specifically, under the following deposition conditions.
Sputtering gas: an Ar/oxygen mixed gas (O₂: 15 vol % or more). Gas pressure; from 5.0×10⁻² to 1.0×10° Pa, preferably from 1.0×10⁻¹ to 8.0×10⁻¹ Pa, more preferably from 2.0×10⁻¹ to 4.0×10⁻¹ Pa.
Input power density per target area: from 2.0 W/cm² to 13.0 W/cm², preferably from 3.0 W/cm² to 12.0 W/cm², more preferably from 4.0 W/cm² to 10.0 W/cm².
Deposition rate: from 0.010 nm/sec to 0.400 nm/sec, preferably from 0.015 nm/sec to 0.300 nm/sec, more preferably from 0.020 nm/sec to 0.200 nm/sec.
Target-to-substrate distance: from 50 mm to 500 mm, preferably from 100 mm to 400 mm, more preferably from 150 mm to 300 mm.

In the case of using an inert gas other than Ar, the concentration of the inert gas is regulated to a value in the same range as the Ar gas concentration shown above. In the case of using a plurality of inert gases, the total concentration of the inert gases is regulated to a value in the same range as the Ar gas concentration shown above.

The EUV mask blank 1 of the present invention may have a functional film known in the field of EUV mask blanks, besides the multilayer reflective film 12, protective film 13, phase shift film 14, and etching mask film 15. Specific examples of such a functional film include a high dielectric coating applied to the back surface of the substrate so as to promote electrostatic chucking of the substrate, such as that described in JP-T-2003-501823 (the term “JP-T” as used herein means a published Japanese translation of a PCT patent application). Here, with respect to the substrate 11 of FIG. 1, the term “back surface of the substrate” means the surface on the opposite side from the surface where the multilayer reflective film 12 has been formed. In applying the high dielectric coating to the back surface of the substrate for such a purpose, the electrical conductivity of a constituent material and a thickness are selected so as to result in a sheet resistance of 100 Ω/sq or less. The constituent material of the high dielectric coating can be selected widely from those described in known literature. For example, the high dielectric coating described in JP-T-2003-501823, specifically a coating composed of silicon, TiN, molybdenum, chromium, and TaSi, can be applied. The thickness of the high dielectric coating may be, for example, from 10 nm to 1,000 nm.

The high dielectric coating can be formed using a known deposition method, e.g., a sputtering method such as magnetron sputtering method or ion beam sputtering method, a CVD method, a vacuum vapor deposition method, or an electrolytic plating method.

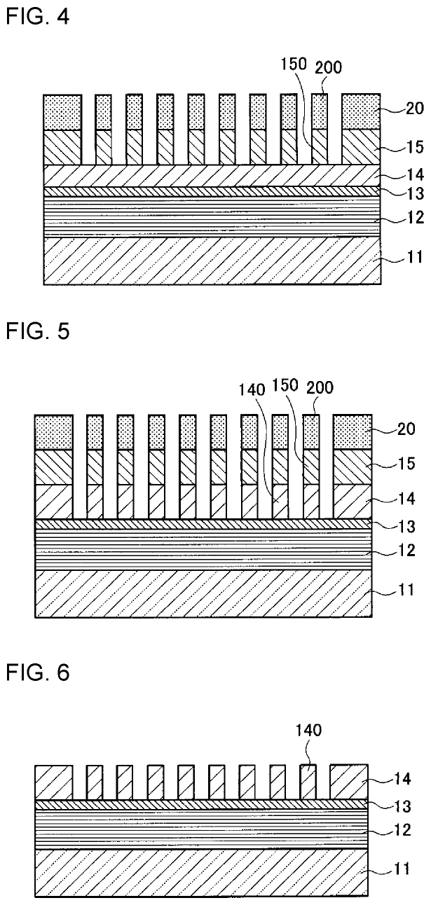

Next, a procedure for patterning the EUV mask blank of the present invention is explained while referring to FIG. 2 to FIG. 6. In the case of patterning the EUV mask blank 1 shown in FIG. 1, a resist film 20 is formed on the etching mask film 15 of the EUV mask blank 1 as shown in FIG. 2. Next, a resist pattern 200 is formed in the resist film 20, as shown in FIG. 3, using an electron-beam drawing machine. Next, the resist film 20 in which the resist pattern 200 has been formed is used as a mask to form an etching mask film pattern 150 in the etching mask film 15 as shown in FIG. 4. For patterning the etching mask film 15 constituted of a Nb-based material, dry etching may be performed using a chlorine-based gas as an etching gas. Next, the etching mask film 15 in which the etching mask film pattern 150 has been formed is used as a mask to form a phase shift film pattern 140 in the phase shift film 14 as shown in FIG. 5. For patterning the phase shift film 14 constituted of a Ru-based material, dry etching may be performed using, as an etching gas, either oxygen gas or a mixed gas of oxygen gas and a halogen-based gas (chlorine-based gas or fluorine-based gas). Next, as shown in FIG. 6, the resist film 20 and the etching mask film 15 are removed with a cleaning liquid including an acid or base to expose the phase shift film pattern 140. Although the resist pattern 200 and the resist film 20 have been mostly removed during the formation of the phase shift film pattern 140, the cleaning with the cleaning liquid including an acid or base is performed for the purpose of removing the remaining resist pattern 200 and resist film 20 and the etching mask film 15.

### EXAMPLES

The present invention is described in greater detail below by referring to Example, but the present invention is not limited to the Example.

### Experiment Example 1

Materials which might be used as the material of the etching mask film in the present invention were dry-etched with an oxygen/chlorine mixed gas.

A film of each of Ru, RuO₂, Nb, Nb₂O₅, CrO, and RuON was deposited on a Si wafer in a thickness of about 40 nm by DC or reactive sputtering in the following manner and subjected to plasma etching in which an oxygen/chlorine mixed gas was used as an etching gas.

(Deposition Conditions for Ru Film (DC Sputtering))
Target: Ru target
Sputtering gas: Ar gas (gas pressure, 0.2 Pa)
Voltage: 400 V
Deposition rate: 0.11 nm/sec

(Deposition Conditions for RuO₂ Film (Reactive Sputtering))
Target: Ru target
Sputtering gas: Ar/O₂ mixed gas (Ar:O₂=5:1; gas pressure, 0.2 Pa)
Voltage: 450 V
Deposition rate: 0.2 nm/sec

(Deposition Conditions for Nb Film (DC Sputtering))
Target: Nb target
Sputtering gas: Ar gas (gas pressure, 2.0×10⁻² Pa)
Voltage: 500 V
Deposition rate: 0.15 nm/sec

(Deposition Conditions for Nb₂O₅ Film (Reactive Sputtering))
Target: Nb target
Sputtering gas: Ar/O₂ mixed gas (Ar:O₂=4:1; gas pressure, 0.2 Pa)
Voltage: 530 V
Deposition rate: 0.025 nm/sec

(Deposition Conditions for CrO Film (Reactive Sputtering))
Target: Cr target
Sputtering gas: Ar/O₂ mixed gas (Ar:O₂=4:1; gas pressure, 0.2 Pa)
Voltage: 350 V
Deposition rate: 0.4 nm/sec

(Deposition Conditions for RuON Film (Reactive Sputtering))
Target: Ru target
Sputtering gas: Ar/O₂/N₂ mixed gas (Ar:O₂:N₂=5:1:1; gas pressure, 0.2 Pa)
Voltage: 500 V
Deposition rate: 0.2 nm/sec

In the plasma etching, the samples obtained by depositing Ru, RuO₂, Nb, Nb₂O₅, CrO, and RuON were disposed on the sample table of an ICP (inductively coupled) plasma etching apparatus and subjected to ICP plasma etching under the following conditions to determine etching rates.
ICP antenna bias: 200 W
Substrate bias: 40 W
Etching time: 30 sec
Trigger pressure: 3.0×10⁰ Pa
Etching pressure: 3.0×10⁻¹ Pa
Etching gas: Cl₂/O₂
Gas flow rate (Cl₂/O₂): 10/10 sccm

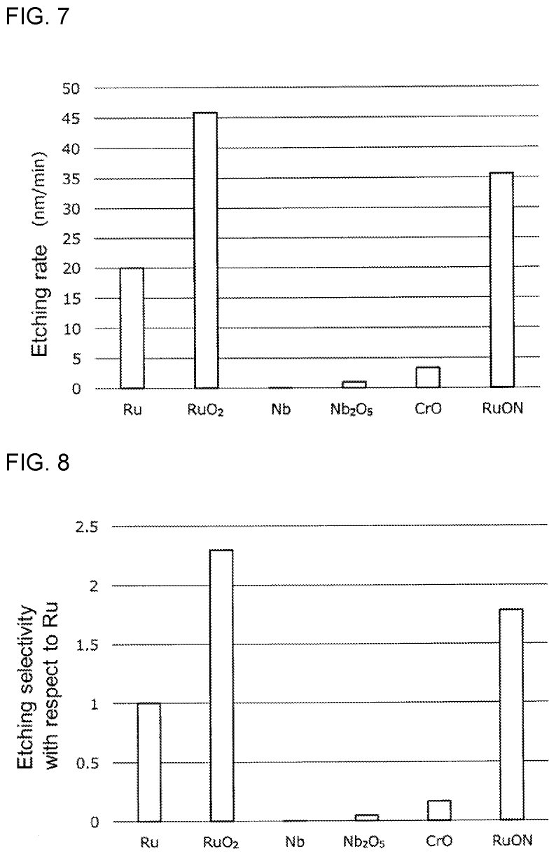

Thereafter, using an X-ray diffractometer (SmartLab HTP, manufactured by Rigaku Corp.), the thickness (nm) of each etched film was measured by X-ray reflectometry (XRR) to determine an etching rate (nm/min). The results thereof are shown in FIG. 7. Furthermore, etching selectivities with respect to Ru were determined as etching rates relative to that of Ru, which was taken as 1. The results thereof are shown in FIG. 8.

It was able to be ascertained that Nb and Nb₂O₅ had low etching selectivities with respect to Ru of 0.0021 and 0.046, respectively. Nb and Nb₂O₅ had low etching selectivities also with respect to other Ru-based materials (RuO₂ and RuON) having higher etching rates than Ru. Specifically, Nb and Nb₂O₅ had low etching selectivities with respect to RuO₂ of 0.0010 and 0.020, respectively, and had low etching selectivities with respect to RuON of 0.0012 and 0.026, respectively. Hence, Nb and Nb₂O₅ are expected to function as the etching mask film in the present invention. Meanwhile, CrO, which has conventionally been used as etching mask films, had an insufficient etching selectivity with respect to Ru of 0.17 and hence does not function as the etching mask film in the present invention.

### Experiment Example 2

The materials which might be used as the material of the etching mask film in the present invention were evaluated for removability by SPM cleaning.

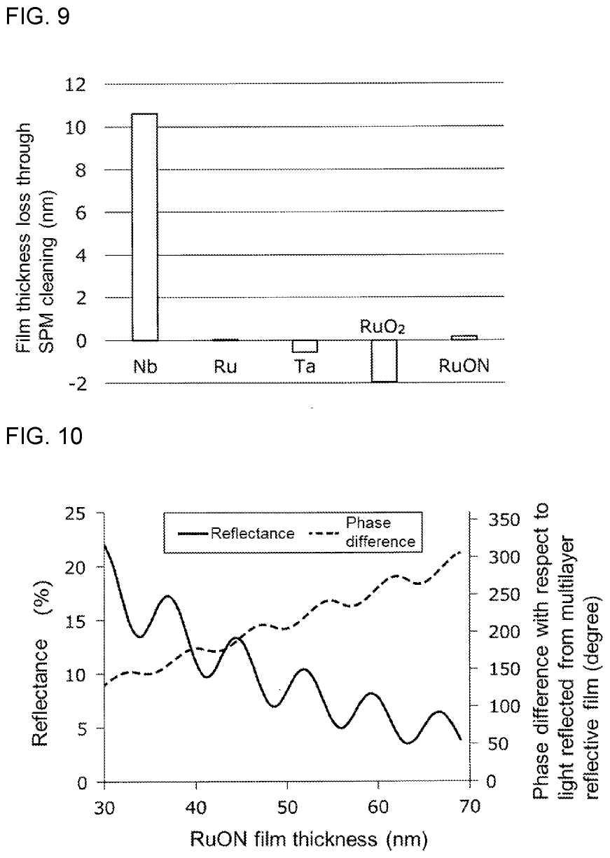

Nb, Ru, Ta, RuO₂, and RuON were each deposited on a Si wafer by DC sputtering in a thickness of about 40 nm, and the thickness of each film was measured using X-ray reflectometry (XRR). Next, an SPM (sulfuric acid, 75 vol %; hydrogen peroxide, 25 vol %) was used as a cleaning liquid, and the Si wafers on which films of the materials including Nb had been deposited by the procedure shown above were immersed for about 20 minutes in the SPM heated at 100° C. After the Si wafers were pulled out of the SPM, the thicknesses of the films of the materials including Nb deposited on the Si wafers were measured to determine film thickness losses (film losses). The change in film thickness of each film through the cleaning is shown in FIG. 9.

As a result, Nb was found to have had a film thickness loss through the SPM cleaning of 10 nm or larger; Nb is hence expected to function as the etching mask film in the present invention. Meanwhile, Ta, which has conventionally been used as etching mask films, showed no film thickness loss through the SPM cleaning and is hence thought to be difficult to remove by SPM cleaning. Although Ta and RuO₂ increased in film thickness through the cleaning, this is thought to be because the cleaning with the SPM, which was a strong acid, resulted in the formation of a passive state on the film surfaces. This formation of a passive state is also an undesirable property of materials for the etching mask film.

### EXAMPLE

In this Example, the EUV mask blank 1 illustrated in FIG. 1 was produced.

As a substrate 11 for deposition, a SiO₂—TiO₂-based glass substrate (outer shape, about 152-mm square; thickness, about 6.3 mm) was used. This glass substrate had a coefficient of thermal expansion of 0.02×10⁻⁷/° C. or less. This glass substrate was polished to make the substrate have a smooth surface with a surface roughness of 0.15 nm or less in terms of root-mean-square roughness Rq and a flatness of 100 nm or less. On the back surface of the glass substrate, a Cr layer with a thickness of about 100 nm was deposited using a magnetron sputtering method to form a back-surface electroconductive layer for electrostatic chucking. The Cr layer had a sheet resistance of about 100 Ω/sq.

After the formation of the electroconductive layer on the back surface of the substrate, an operation of alternately depositing a Si film and a Mo film on the front surface of the substrate using a reactive sputtering method was repeated for 40 cycles. The Si film had a film thickness of about 4.5 nm and the Mo film had a film thickness of about 2.3 nm. Thus, a multilayer reflective film 12 having a total film thickness of about 272 nm ([4.5 nm (Si film)+2.3 nm (Mo film)]×40) was formed. Thereafter, RuZr (film thickness, about 2.5 nm) was deposited on the multilayer reflective film 12 using a DC sputtering method, thereby forming a protective film 13. The resultant structure had a reflectance for 13.53-nm wavelength of 64%.

A RuON film was deposited on the protective film 13 using a reactive sputtering method, thereby forming a phase shift film 14. The deposition of the RuON film was conducted using a Ru target and using, as a sputtering gas, a mixed gas (gas pressure, 0.2 Pa) including Ar, O₂, and N₂ in a volume ratio of 5:1:1 under the conditions of an input power of 450 W. In FIG. 10 are shown: a relationship between the film thickness of the RuON film and reflectance; and phase differences between light reflected from the RuON film and light reflected from the multilayer reflective film.

FIG. 10 shows that the RuON, when having a film thickness of about 44 nm, had a reflectance peak of 13% and the phase difference between light reflected from the RuON film and light reflected from the multilayer reflective film was 184°. The RuON, when having a film thickness of about 52 nm, had a reflectance peak of 10% and the phase difference between light reflected from the RuON film and light reflected from the multilayer reflective film was 221°. These RuON films satisfy the preferred requirements for the phase shift film in the present invention.

After RuON had been deposited in a thickness of 52 nm under those conditions to form a phase shift film 14, a Nb₂O₅ film was deposited using reactive sputtering, thereby forming an etching mask film 15. The deposition of the Nb₂O₅ film was conducted so as to result in a film thickness of 10 nm using a Nb target and using, as a sputtering gas, a mixed gas (gas pressure, 0.2 Pa) including Ar and O₂ in a volume ratio of 5:2 under the conditions of an input power of 650 W. Thus, the EUV mask blank 1 illustrated in FIG. 1 was obtained.

As described above, the present invention provides the following reflective mask blank for EUV lithography, reflective mask for EUV lithography, and methods for producing these.

(1) A reflective mask blank for EUV lithography which includes, in the following order, a substrate, a multilayer reflective film for reflecting EUV light, a phase shift film for shifting a phase of EUV light, and an etching mask film,

wherein the phase shift film is constituted of a ruthenium-based material including ruthenium as a main component,

the phase shift film has a film thickness of 20 nm or larger, and

the etching mask film is removable with a cleaning liquid including an acid or a base.

(2) The reflective mask blank for EUV lithography according to (1) above wherein the etching mask film includes at least one element selected from the group consisting of Nb, Ti, Mo, and Si.

(3) The reflective mask blank for EUV lithography according to (2) above wherein the etching mask film further contains at least one element selected from the group consisting of O, N, and B.

(4) The reflective mask blank for EUV lithography according to any one of (1) to (3) above wherein the etching mask film has a film thickness of 20 nm or less.

(5) The reflective mask blank for EUV lithography according to any one of (1) to (4) above wherein the etching mask film is removable with any one cleaning liquid selected from the group consisting of a sulfuric acid/hydrogen peroxide mixture, an ammonia/hydrogen peroxide mixture, and hydrofluoric acid.

(6) The reflective mask blank for EUV lithography according to any one of (1) to (5) above, wherein when dry-etched using as an etching gas either oxygen gas or a mixed gas of oxygen gas and a halogen-based gas, the etching mask film has an etching selectivity with respect to the phase shift film of 1/10 or less.

(7) The reflective mask blank for EUV lithography according to any one of (1) to (6) above wherein the phase shift film constituted of a ruthenium-based material is formed of a material which is etchable at an etching rate of 10 nm/min or higher by dry etching using either oxygen gas or a mixed gas of oxygen gas and a halogen-based gas.

(8) The reflective mask blank for EUV lithography according to any one of (1) to (7) above wherein the phase shift film has a film thickness of from 20 nm to 60 nm.

(9) The reflective mask blank for EUV lithography according to any one of (1) to (8) above wherein the phase shift film has a reflectance at 13.53-nm wavelength of from 3% to 30%, and

a phase difference between a reflected light of EUV light from the multilayer reflective film and a reflected light of EUV light from the phase shift film is from 150° to 250°.

(10) The reflective mask blank for EUV lithography according to any one of (1) to (9) above which includes a protective film for the multilayer reflective film, disposed between the multilayer reflective film and the phase shift film.

(11) The reflective mask blank for EUV lithography according to (10) above wherein the protective film includes at least one element selected from the group consisting of Ru, Pd, Ir, Rh, Pt, Zr, Nb, Ta, Ti, and Si.

(12) The reflective mask blank for EUV lithography according to (11) above wherein the protective film further contains at least one element selected from the group consisting of O, N, and B.

(13) A reflective mask for EUV lithography obtained by forming a pattern in the phase shift film of the reflective mask blank for EUV lithography according to any one of (1) to (12) above.

(14) A method for producing the reflective mask blank for EUV lithography according to any one of (1) to (12) above, the method including

a step in which a multilayer reflective film is formed on or above the substrate,

a step in which a phase shift film including ruthenium is formed on or above the multilayer reflective film, and

a step in which an etching mask film is formed on or above the phase shift film.

(15) A method for producing a reflective mask for EUV lithography, wherein the phase shift film of the reflective mask blank for EUV lithography produced by the method according to (14) above for producing a reflective mask blank for EUV lithography is patterned to form a mask pattern.

While the invention has been described in detail and with reference to specific embodiments thereof, it will be apparent to one skilled in the art that various changes and modifications can be made therein without departing from the spirit and scope thereof.

### REFERENCE SIGNS LIST

1: EUV mask blank
11: Substrate
12: Multilayer reflective film
13: Protective film
14: Phase shift film
15: Etching mask film
20: Resist film
140: Phase shift film pattern
150: Etching mask film pattern
200: Resist pattern

1. A reflective mask blank for EUV lithography comprising, in the following order, a substrate, a multilayer reflective film for reflecting EUV light, a phase shift film for shifting a phase of EUV light, and an etching mask film,
wherein the phase shift film is constituted of a ruthenium-based material comprising ruthenium as a main component,
the phase shift film has a film thickness of 20 nm or larger, and
the etching mask film is removable with a cleaning liquid comprising an acid or a base.

2. The reflective mask blank for EUV lithography according to claim 1, wherein the etching mask film comprises at least one element selected from the group consisting of Nb, Ti, Mo, and Si.

3. The reflective mask blank for EUV lithography according to claim 2, wherein the etching mask film further comprises at least one element selected from the group consisting of O, N, and B.

4. The reflective mask blank for EUV lithography according to claim 1, wherein the etching mask film has a film thickness of 20 nm or less.

5. The reflective mask blank for EUV lithography according to claim 1, wherein the etching mask film is removable with any one cleaning liquid selected from the group consisting of a sulfuric acid/hydrogen peroxide mixture, an ammonia/hydrogen peroxide mixture, and hydrofluoric acid.

6. The reflective mask blank for EUV lithography according to claim 1, wherein when dry-etched using as an etching gas either oxygen gas or a mixed gas of oxygen gas and a halogen-based gas, the etching mask film has an etching selectivity with respect to the phase shift film of 1/10 or less.

7. The reflective mask blank for EUV lithography according to claim 1, wherein the phase shift film constituted of a ruthenium-based material is formed of a material which is etchable at an etching rate of 10 nm/min or higher by dry etching using either oxygen gas or a mixed gas of oxygen gas and a halogen-based gas.

8. The reflective mask blank for EUV lithography according to claim 1, wherein the phase shift film has a film thickness of from 20 nm to 60 nm.

9. The reflective mask blank for EUV lithography according to claim 1,
wherein the phase shift film has a reflectance for 13.53-nm wavelength of from 3% to 30%, and
a phase difference between a reflected light of EUV light from the multilayer reflective film and a reflected light of EUV light from the phase shift film is from 150° to 250°.

10. The reflective mask blank for EUV lithography according to claim 1, comprising a protective film for the multilayer reflective film, disposed between the multilayer reflective film and the phase shift film.

11. The reflective mask blank for EUV lithography according to claim 10, wherein the protective film comprises at least one element selected from the group consisting of Ru, Pd, Ir, Rh, Pt, Zr, Nb, Ta, Ti, and Si.

12. The reflective mask blank for EUV lithography according to claim 11, wherein the protective film further comprises at least one element selected from the group consisting of O, N, and B.

13. A reflective mask for EUV lithography obtained by forming a pattern in the phase shift film of the reflective mask blank for EUV lithography according to claim 1.

14. A method for producing the reflective mask blank for EUV lithography according to claim 1, the method comprising:
forming a multilayer reflective film on or above the substrate;
forming a phase shift film including ruthenium on or above the multilayer reflective film; and
forming an etching mask film on or above the phase shift film.

15. A method for producing a reflective mask for EUV lithography, wherein the phase shift film of the reflective mask blank for EUV lithography produced by the method according to claim 14 for producing a reflective mask blank for EUV lithography is patterned to form a mask pattern.
